(19) United States
(12) Patent Application Publication
(10) Pub. No.: US 2011/0266234 A1
(43) Pub. Date: Nov. 3, 2011

(54) MOUNTING SYSTEM FOR SOLAR MODULES AND METHOD FOR INSTALLING A SOLAR SYSTEM

(75) Inventors: Ralf Ritzler, Bielefeld (DE); Wadim Salzer, Bielefeld (DE); Andreas Rosenwirth, Enger (DE); Gerd Imkamp, Gutersloh (DE); Andre Stockhausen, Herford (DE); Carsten Hanke, Bielefeld (DE)

(73) Assignee: SCHUCO INTERNATIONAL KG, Bielefeld (DE)

(21) Appl. No.: 13/089,564

(22) Filed: Apr. 19, 2011

(30) Foreign Application Priority Data
Apr. 19, 2010 (DE) 10 2010 016 529.8

(51) Int. Cl. H01L 23/12; H01L 31/18

(52) U.S. Cl. 211/41.1; 29/428

(57) ABSTRACT

A mounting system (1) for solar modules (6) having base part (11) on which a frame (2) is supported to which one or more plate-shaped solar modules (6) are held, and having an anchor (13, 35) capable of being attached to a wall of a building structure and which supports the frame (2) in an upper region, wherein the base part (11) is pivotable about a horizontal axis (10). Further, the invention relates to a method for installing a solar system.

The present invention relates to a mounting system for solar modules having a substructure on which a frame is supported to which one or more plate-shaped solar modules are held, and having an anchor capable of being attached to a building structure and which supports the frame in an upper region, as well as a method for installing a solar system.

Mounting systems for solar modules are well known in which a frame is supported on a substructure, for example on pile-driven foundation posts. The frame is thereby mounted at a previously determined angle of pitch either on several of the posts forming the substructure, wherein short front posts are arranged to the south side and longer rear posts arranged to the north side, or on only one post, wherein the frame is supported approximately in the centre so that there is an even distribution of load. These mounting systems can be fixed atop or onto buildings, or onto outdoor open areas. A disadvantage is that, in addition to the frame, relatively complex and expensive substructures have to be provided. In particular, the installation of very large solar systems is difficult and elaborate.

Furthermore, solar module mounting systems integrated into the facades forming part of the building envelope are also well known. In such cases, in addition to the purely retaining function, the systems have to fulfil further functions, like, for example, heat insulation and/or the provision of a waterproof facade or a waterproof section of the facade respectively. Disadvantageous here, however, is that retrofitting on the building envelope is no longer possible, or can be carried out only with considerable effort.

It is, therefore, the object of the present invention to provide a mounting system for solar modules as well as a method for installing a solar system, which can be flexibly adapted to various on-site conditions and which makes a simple installation possible. In addition, the mounting system also has to be suitable for retrofitting on buildings.

In order to achieve this object, a mounting system with the features of claim 1 as well as a method for installing a solar system with the features of claim 7 is provided.

According to the invention, with this mounting system, the base part is swivel-mounted to pivot about a horizontal axis and the frame can be fixed in varying angles of inclination. In this way, a simple pre-assembly of the solar system can take place on the ground, after which the base part together with the frame and the solar modules can be erected and attached to the building structure or other element. This makes it possible to install solar systems effectively on larger areas as well. In addition, it is also possible, by means of the swivel bearing, to carry out an adjustment to the angle of inclination, for example to align optimally the solar modules according to the prevailing season. During the winter months, the position of the sun in the sky is not as high, making a steeper alignment of the solar modules more advantageous. During the summer months, on the other hand, a flatter alignment of the solar modules can increase the efficiency. The adjustment of the inclination can also be done after the first installation.

In a further beneficial embodiment refinement, the substructure bears the occurring weight loads whilst the anchor absorbs the wind loads. Thus, essentially, the mounting elements are only subjected to tensile and compression forces.

The base part is preferably mounted to a stationary part attached at the bottom to a socket or post. Thus, whatever the sub-surface conditions are, it is possible to achieve a stable fastening of the retainer part to which the base part is swivel-mounted. The stationary part and the base part can be connected to each other by means of a hinge joint, which can be constructed with appropriately stable dimensions according to the weight loads occurring.

According to a further embodiment refinement of the invention, the inclination of the frame is adjustable by means of the anchors. For this purpose, the anchors can be constructed to be longitudinally adjustable in order to modify the angle of inclination of the frame by pivoting about the horizontal axis at the base part.

In addition, to enable simple installation, the posts are mounted, preferably longitudinally slidably adjustable, on a retainer part. The retainer part can then be pushed onto the posts at one end in order to be fixed at the desired height. In this way, thermal stress can be avoided. It is an advantage to have corresponding tolerance compensation, which is achieved by sliding the posts relative to the retainer part, particularly when the posts that are used have a greater length, e.g. over 5 m.

According to the invention a method for installing a solar system will also be provided having the following steps:
Fixing a profile to a base part being stationary at the bottom;
Erecting the profile by pivoting about a horizontal axis, and
Attaching a retainer part in the upper region of the profile and fixing the retainer part by means of an anchor to a building structure.

By means of the mounting system according to the invention, standardised procedural steps can be employed in order to install a solar system effectively, so that within a short time even larger areas can be attached. In particular, due to the swivel-mounting of the frame, an appropriate alignment and flexible adjustment can also be undertaken, depending on the various circumstances caused by the condition of the ground and/or the geometry of the building. The retrofitting of a solar system to existing building structures such as the wall or the facade of a building is also possible without any problems.

Preferably, several profiles are joined together by means of transverse bars in order to form a frame before the profiles are erected. Consequently, the solar modules can be fixed to the frame whilst it is on the ground and then erected as one unit, thus avoiding installation at great heights. In the process, the frame, in an intermediate step, can be positioned disposed from the ground in order to fix the solar modules mechanically and to wire them together by cable. The frame can then be erected with the positioned and affixed solar modules as well, so that a complete assembly of the frame with the arranged solar modules takes place at the ground, and is then erected as one unit that then merely needs to be attached to the building or other building structure at the desired position.

The invention will be described subsequently in more detail by means of embodiments in conjunction with the accompanying drawings, wherein:

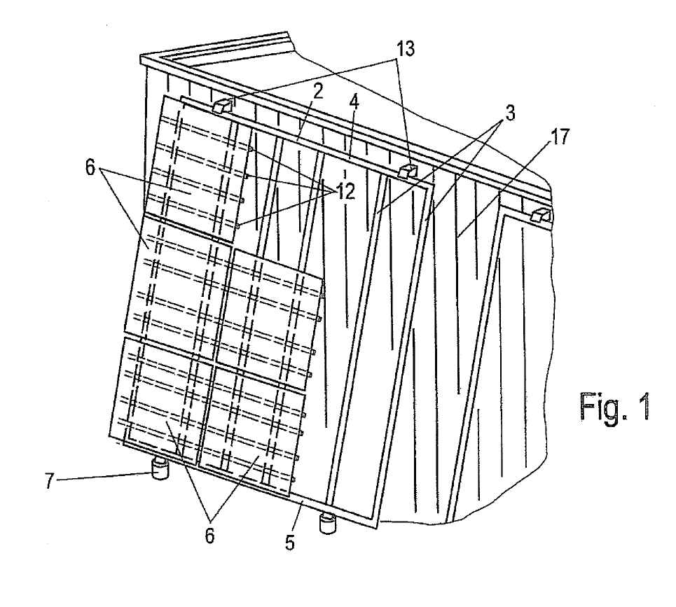

FIG. 1 shows a perspective view of a mounting system for solar modules according to the invention;

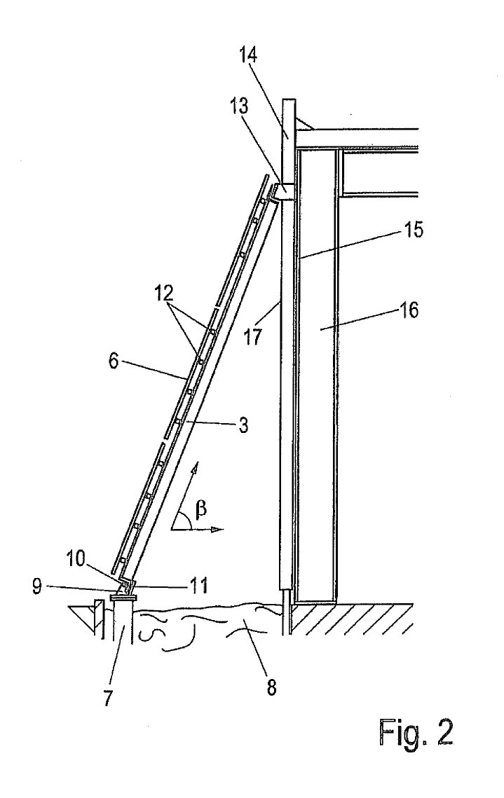

FIG. 2 shows a side view of the mounting system of FIG. 1;

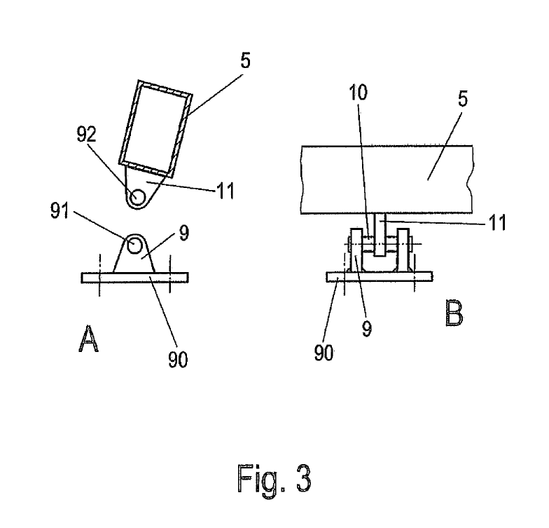

FIGS. 3A and 3B show two views of a base part of the mounting system;

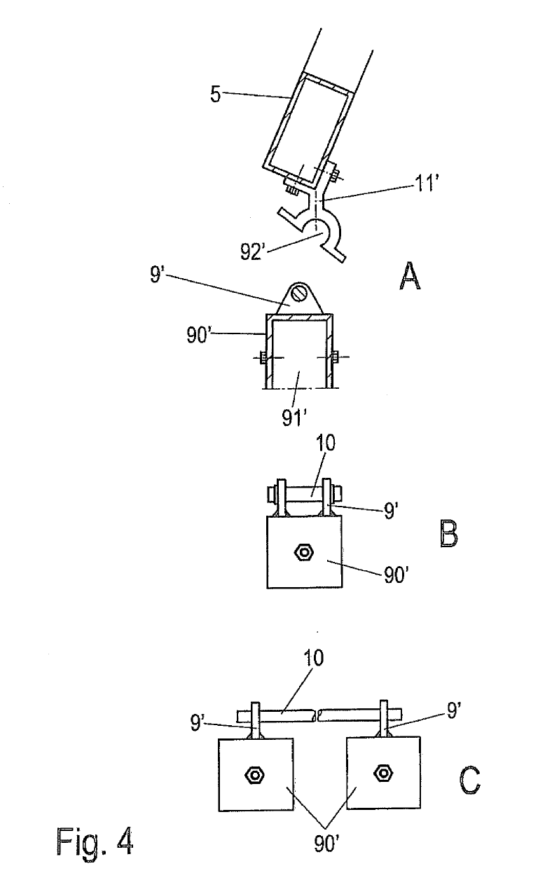

FIGS. 4A to 4C show several views of modified base parts for a mounting system;

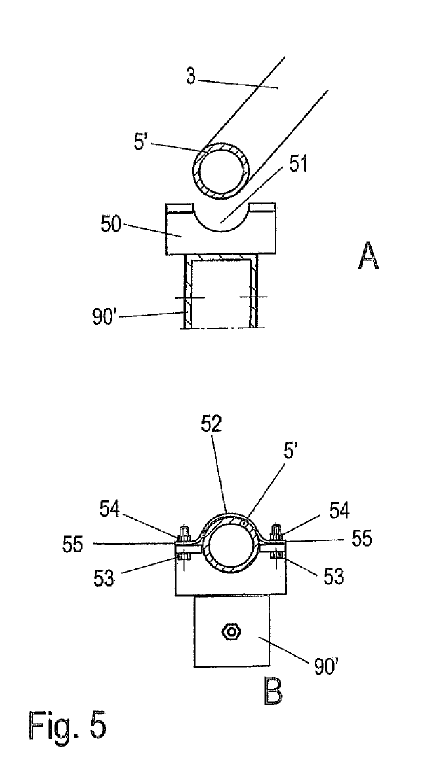

FIGS. 5A and 5B show two views of a further embodiment of a base part;

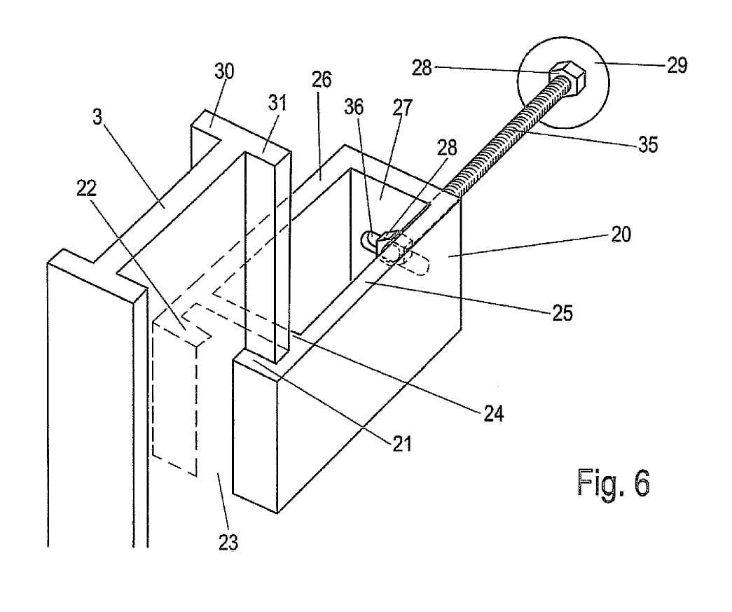

FIG. 6 shows a perspective view of an anchor of the mounting system of FIG. 1;

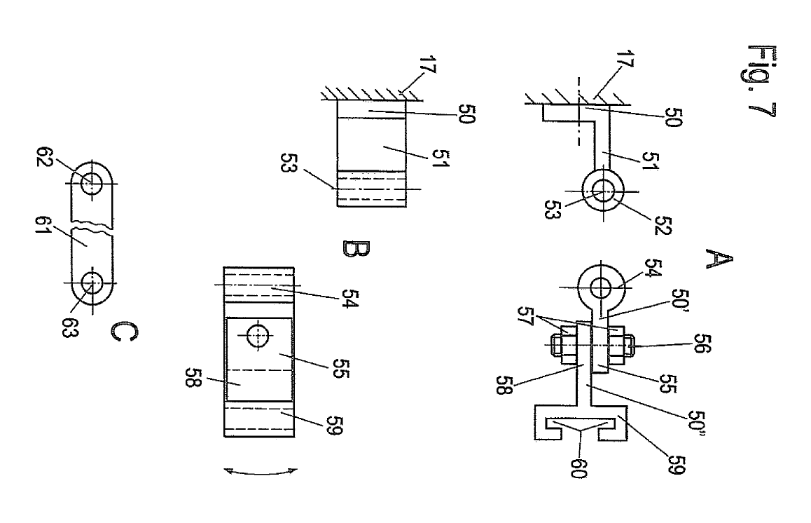

FIGS. 7A to 7C show several views of a further embodiment of an anchor for a mounting system;

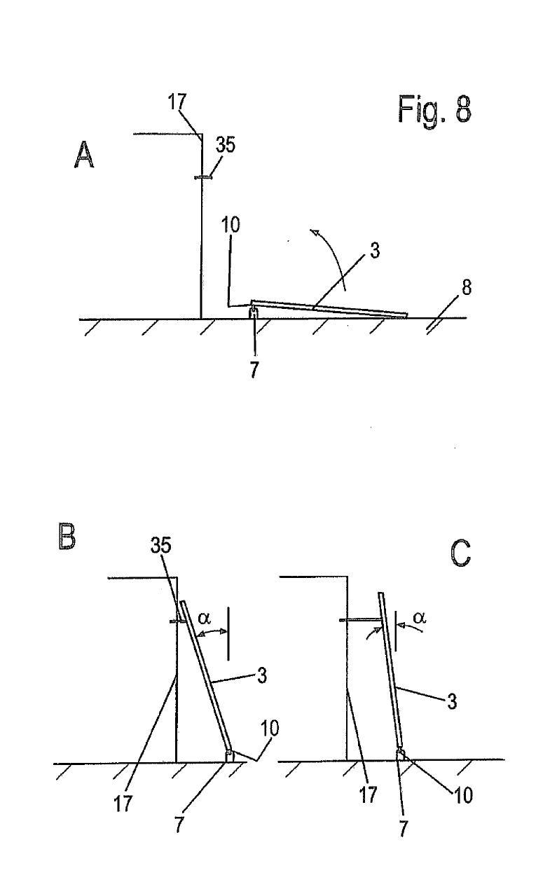

FIGS. 8A to 8C show several schematic views of the mounting system of FIG. 1 during installation;

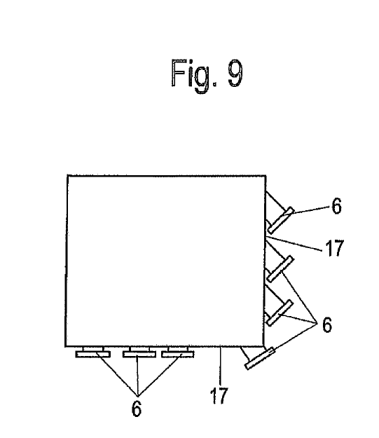

FIG. 9 shows an overhead view of a building with several installed solar modules;

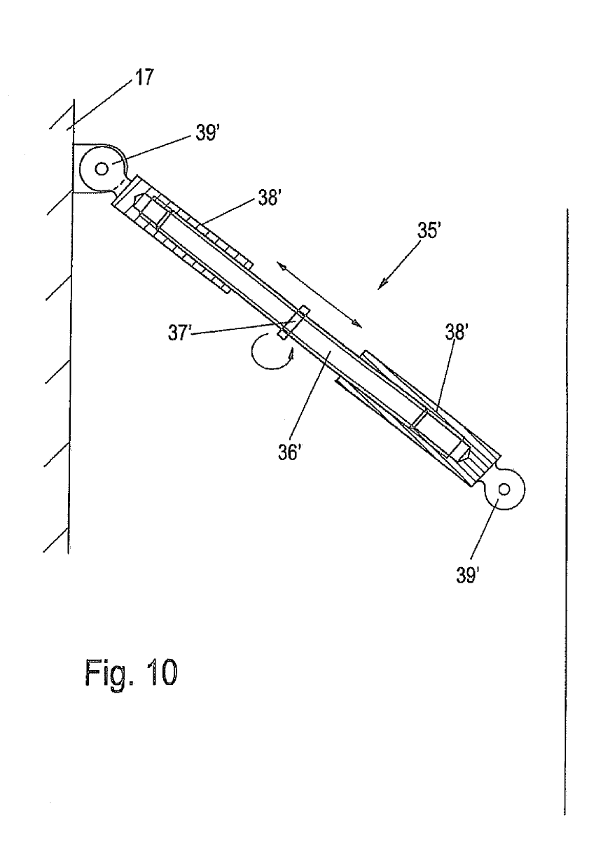

FIG. 10 shows a detailed view of an anchor with lengthwise adjustability, and

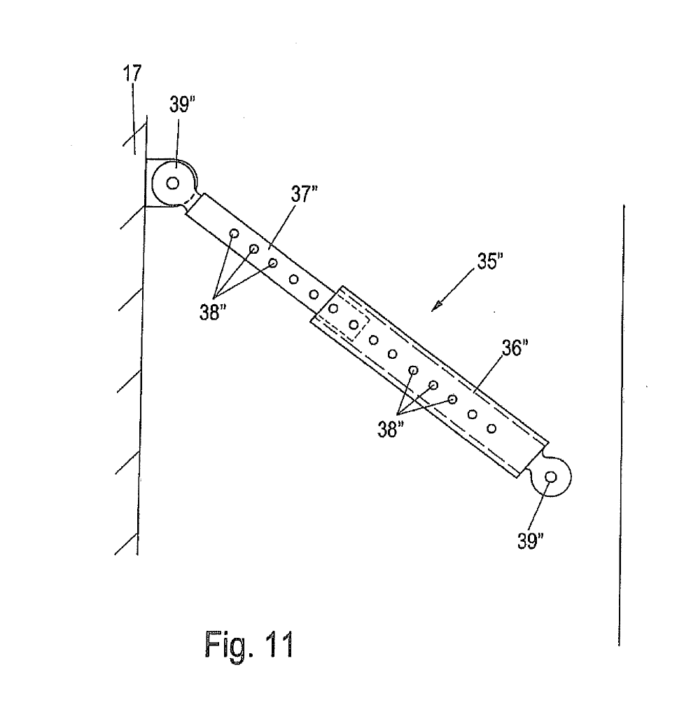

FIG. 11 shows a detailed view of an anchor with lengthwise adjustability having a modified adjustment mechanism.

A mounting system 1 for solar modules comprises a frame 2 consisting of upwardly extending profiles 3 and horizontal profiles 4 and 5, wherein in FIG. 1 solely an upper horizontal profile 4 and a lower horizontal profile 5 are shown. Further horizontal profiles can be arranged in the middle section. One or more solar modules 6 are attached to the frame 2 and held to the frame 2 by means of strip-shaped fixing devices 12.

The frame 2 is supported at the bottom by a substructure that bears almost completely the weight load of the frame 2 with the solar modules 6. The substructure comprises a base part 11 and a stationary part 9, which is attached to a pile-driven foundation post 7 that is anchored in the ground 8 (FIG. 2).

The frame 2 is, in its upper region at certain points that are disposed to each other at intervals, attached to a wall 17 or the facade of a building respectively by means of anchors 13. The frame 2 can also be extended over greater heights, for example over 4 m and higher, and can be installed on the walls of industrial premises. In order to obtain an optimal angle of pitch 13 corresponding to the on-site conditions, the base part is disposed at a distance from the wall 17 of the building, wherein the angle of pitch lies, for example, within a range of between 60° and 80°. The wall 17 of the building comprises an insulation 14 that is arranged adjacent to an interior wall 15. A post 16 is arranged in the interior area, which is necessary for structural purposes and to which an anchor 13 can be attached. It is possible to include a counter bearing for the anchor 13 in the interior area.

FIGS. 3A and 3B depict a base part 11 that is formed as a lug and welded to the bottom part of a cross member 5. The base part 11 includes an opening 92 through which the one axis 10 can be inserted. To provide pivotable positioning of the base part 11, a stationary part 9 is provided formed out of two lugs also having an opening 91 to allow for the insertion of the axis 10. The two lugs are joined to each by means of a mounting plate 90 and are welded there. The mounting plate 90 can be fixed to a base made of concrete, for example, or to a post.

FIG. 4A shows a modified base part 11′ that can be screwed on the lower transverse bar of the mounting system 1. For this, the base part 11′ includes an angular section that partially grips around an edge of the transverse bar 5. Appropriate screw fittings can be provided on the legs of the angle.

Further, the base part 11′ includes a semi-circular holder 92′ that can be turned around an axis 10. The axis 10 (FIG. 4B) is fixed to two lugs of a stationary part 9′, wherein the lug 9′ is welded to a hollow attachment 90′. The attachment 90′ features an internal holder 91′ that can, for example, be mounted onto and screwed into a pile-driven foundation post.

As shown in FIG. 4C, by assembling several neighbouring attachments 90′, a relatively long axis 10 can be supported between two stationary parts 9′. The base part 11 with the semi-circular holder 92′ can then be attached to the anchor.

The FIGS. 5A and 5B depict a further embodiment, wherein the frame 2 comprises a semi-circular hollow profile as a lower transverse bar 5′. The transverse bar 5′ is pivotably supported in a semi-circular holder 51 of a retainer part 50, wherein the retainer part 50 is fixed at the bottom to an attachment 90′ or to another fixing device. After the installation of the retainer part 50, the lower transverse bar 5′ is inserted into the holder 51 and then subsequently secured with strips 52 that are fixed to the retainer part 50 by means of fixing devices 53.

FIG. 6 depicts the mounting for a post 3 rising at an angle of pitch 13 and which is designed as a double-T-profile or I-beam having accordingly at each opposing end two laterally protruding webs 30 and 31 that are connected to each other by a central web 32. The profile 3 is slidably positioned relative to a retainer 20, which is designed in a U-shape or channel and has two brackets 25 and 26 that are connected to each other by a bottom side 27. In order to slidably position the profile 3, on the brackets 25 and 26 there are inwardly directed webs 21 and 22 as well as a connecting web 24 designed to clasp the webs 30 and 31 of profile 3. The central web 32 is guided through a slit 23 between the webs 21 and 22. Thus, the profile 3 can be moved in a longitudinal direction whilst still being held by the retainer 20.

An anchor 35 designed as a threaded rod is arranged on the bottom side 27 and attached to a post 16 of the building or to another structural element of the building or building structure. At a duct in a wall, a seal 29 is attached by means of a nut 28 to the anchor 35. Likewise, the retainer 20 is fixed in the desired position by means of nuts 28. For this purpose, a horizontal slot 36 is formed in the bottom side 27. By means of this horizontal slot 36, a horizontal repositioning of the retainer part relative to the anchor 35 that is fixed to the wall can be carried out, so that when fixing the profile 3, an alignment both in a horizontal direction parallel to the wall as well as perpendicular to the wall can be achieved when the retainer part 20 is fixed using two nuts 28. The anchor 35 can thereby be fixed to the building construction in a horizontal inclination, so that the anchor 35 and the profile are arranged essentially at right angles to each other.

FIGS. 7A to 7C show a further design refinement of a multi-part retainer element used to fix a frame 2 to a wall 17 of a building. A first anchor part 50 is attached to a schematically depicted wall 17 and includes a protruding section 51 to which a sleeve 52 is arranged to form a rotational axis 53. A second sleeve 54 of a second anchor part 50′ is attached to the sleeve 52 by means of a not shown axis wherein the second anchor part 50′ includes a sleeve 55 at the opposite side and through which an axis 56 extends. At the axis 56, a sleeve 58 of a third anchor part 50″ is fixed, through which the axis 56 also extends, wherein the second anchor part 50′ and the third anchor part 50″ are secured to each other on the axis 56 by means of nuts 57.

On the third anchor part 50″, a guidance element 59 is arranged with grooves 60 to allow for the introduction of a section of a profile 3.

The attachment of the sleeves 52 and 54 can be carried out as with the sleeves 55 and 58, so that the third anchor part 50″ is positioned to pivot about both a horizontal axis as well as a vertical axis at the first anchor part 50.

In addition, an extension element 61 can be fitted between the sleeve 52 and the sleeve 54 and which features openings 62 and 63 at the opposing ends into which the appropriate axes can be inserted.

FIGS. 8A to 8C schematically depict the installation of a mounting system according to the invention. FIG. 8A depicts at the base side a pile-driven foundation post 7 mounted into the ground 8 and to which a stationary part 9 of the ground part is attached. Attached to a swivel-mounted retainer part 11 positioned to pivot about an axis 10, is a profile 3 that lies on the ground and whilst on the ground can be connected to additional profiles 3 by means of horizontal profiles 4 and 5 to form a frame 2. The frame 2 can then be brought into an intermediate position disposed from the ground in order to mount the solar modules. Furthermore, the necessary anchors 35 are attached to a wall 17 of the building.

Subsequently, the posts 3 are swung up into position, either separately or together with the frame 2 as wished. Afterwards, a retainer part 20, 20′ or the third anchor part 59′ is slid onto the profile 3 and attached to the anchor 35. In the process, profile 3 and therefore also the solar modules 6 are brought into an angled position α relative to the vertical. The angle of pitch α can be chosen to be somewhat greater or smaller depending on the prevailing season, preferably between 60° and 80°.

FIG. 9 schematically depicts a building with several solar modules 6 mounted on a mounting system according to the invention. As the frame 2 is positioned to pivot about the base part, the angle of pitch α can be adjusted. Furthermore, it is also possible to align the solar panels at an angle to the surface of a wall 17 of the building, as shown on the right side of the drawing. To this end, for example, a multi-part anchor 50, 50′ and 50″ is used that allows for an appropriate optimal alignment when attaching the solar modules 6.

FIG. 10 schematically depicts a longitudinally slidable anchor 35′ having a rod-shaped threaded portion 36′ provided with a centrally placed tool attachment section 37′ and screwed at the opposing ends into a sleeve 38′. A connection point 39′ is provided at the sleeve 38′ in order to be able to connect the anchor 35′ to a wall 17 of a building or respectively to a retainer 20, 20′ or 40. By changing the length of the anchor 35′, the angle of inclination of the solar modules can be adjusted.

FIG. 11 depicts a modified design refinement of an anchor 35″, which likewise is longitudinally adjustable. To this end, a bar 37″ engages with a sleeve 36″ wherein both in the bar as well as in the sleeve 36″ openings 38″ have been formed through which appropriate pins can be inserted for fastening purposes. A point of attachment 39″ is arranged on the bar 37″ to enable the connection to a wall 17, and, equally, there is a point of attachment 39″ on the sleeve 36″ to enable a connection to a retainer part 20.

In the depicted embodiment examples, the retainer parts 20, 20′, 59 are each mounted on a profile 3 that is slidably positioned. It is, of course, also possible to mount additional components to the frame 2 to allow for slidable positioning relative to a stationary anchor.

1. Mounting system (1) for solar modules (6) having a substructure (7,9,11) on which a frame (2) is supported to which one or more plate-shaped solar modules (6) are held, and having an anchor (13, 35) capable of being attached to a building structure and which supports the frame (2) in an upper region, characterized in that the base part (11) is pivotable about a horizontal axis (10) and that the frame (2) can be fixed in various angles of inclination.

2. Mounting system according to claim 1, characterized in that the weight loads of the frame (2) and the solar modules (6) are essentially born by the substructure.

3. Mounting system according to claim 1 or 2, characterized in that the base part (11) is mounted to a stationary part (9) attached at the bottom to a socket or post (7).

4. Mounting system according to claim 3, characterized in that the stationary part (9) and the base part (11) are connected to each other by means of a hinge joint.

5. Mounting system according to any one of claims 1 to 4, characterized in that the inclination of the frame (2) relative to the horizontal is adjustable by means of the anchor (13, 35) or retainer part (20, 20′, 61).

6. Mounting system according to any one of claims 1 to 5, characterized in that profiles (3) are positioned longitudinally slidably relative to a retainer part (20) being connected to the anchor (13, 35).

7. Method for installing a solar system having the following steps:
Fixing a profile (3) to a base part (11) being stationary at the bottom;
Erecting the profile (3) by pivoting about a horizontal axis (10), and
Attaching a retainer part (20) in the upper region of the profile (3) and fixing the retainer part (20) by means of an anchor (13, 35) to a building structure.

8. Method according to claim 7, characterized in that several profiles (3) by means of transverse bars (4, 5) are connected to each other in order to form a frame (2) before the profiles (3) are erected.

9. Method according to claim 8, characterized in that the frame (2) is swung into an intermediate position disposed from the ground and supported there in order to at least partially mount the solar modules (6).

10. Method according to claim 9, characterized in that the frame (2) is erected with the solar modules being attached (6).
